(19) United States
(12) Patent Application Publication
(10) Pub. No.: US 2006/0281282 A1
(43) Pub. Date: Dec. 14, 2006

(54) Method for maching a wafer

(76) Inventors: Fu Tang Chu, Kaoshiung (TW); Chi Yuam Chung, Kaoshiung (TW); Chi Ping Teng, Kaoshiung (TW)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/447,088

(22) Filed: Jun. 6, 2006

(30) Foreign Application Priority Data
Jun. 8, 2005 (TW) 094118939

(51) Int. Cl. H01L 21/00

(52) U.S. Cl. 438/464

(57) ABSTRACT

The present invention relates to a method for machining a wafer, comprising: (a) providing a wafer having an active surface and a backside surface; (b) attaching a plate substrate to the active surface of the wafer; (c) grinding the backside surface of the wafer; (d) removing the plate substrate; and (e) sawing the wafer. Therefore, warping of the thin wafer can be avoided.

### BACKGROUND OF THE INVENTION 1. Field of the Invention

The present invention relates to a method for machining a wafer, and more particularly, to a method for machining a wafer supported by a substrate. 2. Description of the Related Art

Referring to FIGS. 1 to 6, schematic views illustrating a conventional method for machining a wafer are shown. Firstly, referring to FIG. 1, a wafer 10 having an active surface 101 and a backside surface 102 is provided, wherein the active surface 101 has a plurality of solder pads or sawing lines (not shown), etc. Then, a back grinding tape 12 is adhered onto the active surface 101, so as to protect the active surface 101 during the subsequent grinding process.

Then, referring to FIG. 2, the wafer 10 is turned over 180 degrees, so that its backside surface 102 faces upwards, and the wafer 10 is placed onto a grinding machine. The backside surface 102 of the wafer 10 is ground by a grinding wheel 14 of the grinding machine.

Then, referring to FIG. 3, a sawing adhesive film 16 is provided, and the sawing adhesive film 16 is adhered to the ground backside surface 102 of the wafer 10.

Then, referring to FIG. 4, the wafer 10 is again turned over 180 degrees, such that its active surface 101 faces upwards. The wafer 10 is adhered onto a frame 18 through the sawing adhesive film 16. After that, the back grinding tape 12 is torn off, so as to expose the active surface 101 of the wafer 10.

Then, referring to FIG. 5, the wafer 10 is sawed along the sawing lines on the active surface 101 of the wafer 10 by a blade 20, to form a plurality of dies 22 (FIG. 6). After that, the dies 22 are picked out and then adhered onto a substrate 26 by a liquid adhesive (e.g., a silver gel) 24, as shown in FIG. 6.

The disadvantage of the conventional method for machining a wafer is that, as the wafer 10 gradually gets thinner, and the sawing adhesive film 16 and the back grinding tape 12 are thin films themselves, warping of the wafer 10 will easily occur during the processes of moving, adhering, grinding, sawing, etc., which results in machining difficulties, or even in a situation where the machining cannot be carried out accordingly. In addition, when the thickness of the wafer 10 is less than about 75 μm, if the back grinding tape 12 itself has been cut poorly, the grinding process will be affected. Finally, glue overflow will easily occur for the conventional liquid adhesive 24 in the process of adhering the dies 22, so that the adhesive quality will be affected.

Consequently, there is an existing need for a method for machining a wafer to solve the above-mentioned problems.

### SUMMARY OF THE INVENTION

The objective of the present invention is to provide a method for machining a wafer, which is a method for machining a wafer supported by a substrate, thereby, avoiding any warp in the wafer when the method is applied to an ultra-thin wafer.

Another objective of the present invention is to provide a method for machining a wafer, wherein a semi-solid adhesive paste is used to replace the conventional sawing adhesive film and the liquid adhesive, thus lowering the cost. The glue overflow will not occur after the dies are bonded, and the yield of the package product is improved.

Yet another objective of the present invention is to provide a method for machining a wafer, comprising:

(a) providing a wafer having an active surface and a backside surface;

(b) attaching a plate substrate to the active surface of the wafer;

(c) grinding the backside surface of the wafer;

(d) removing the plate substrate; and

(e) sawing the wafer.

### BRIEF DESCRIPTION OF THE DRAWINGS

FIGS. 1 to 6 are schematic views illustrating a conventional method for machining a wafer; and

FIGS. 7 to 13 are schematic views illustrating a method for machining a wafer according to the present invention.

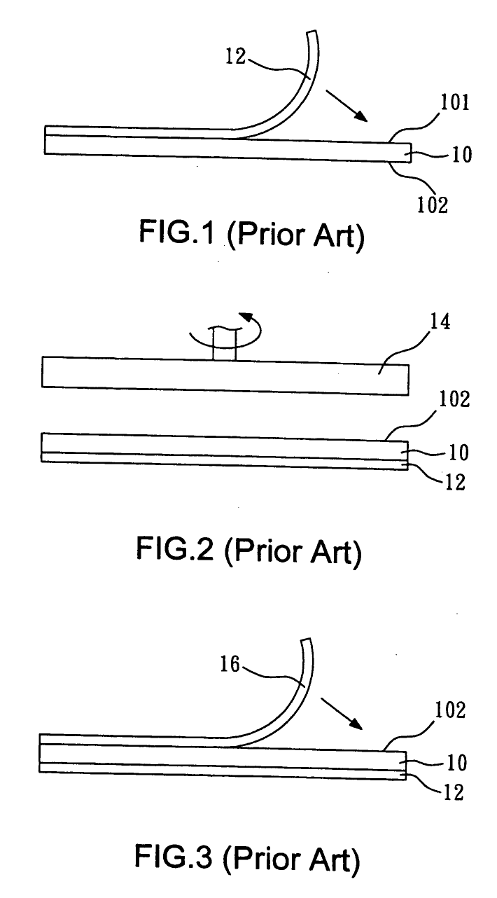

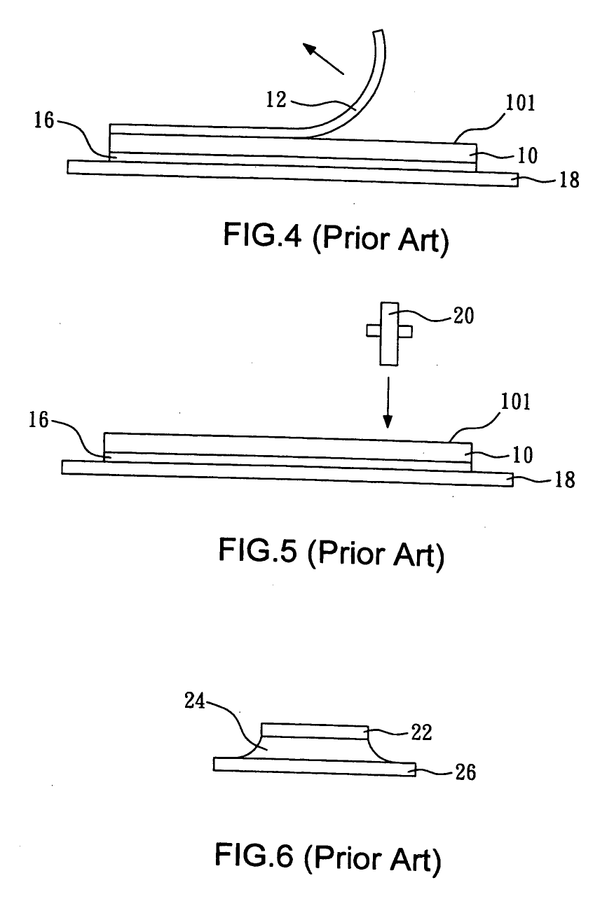

### DETAILED DESCRIPTION OF THE INVENTION

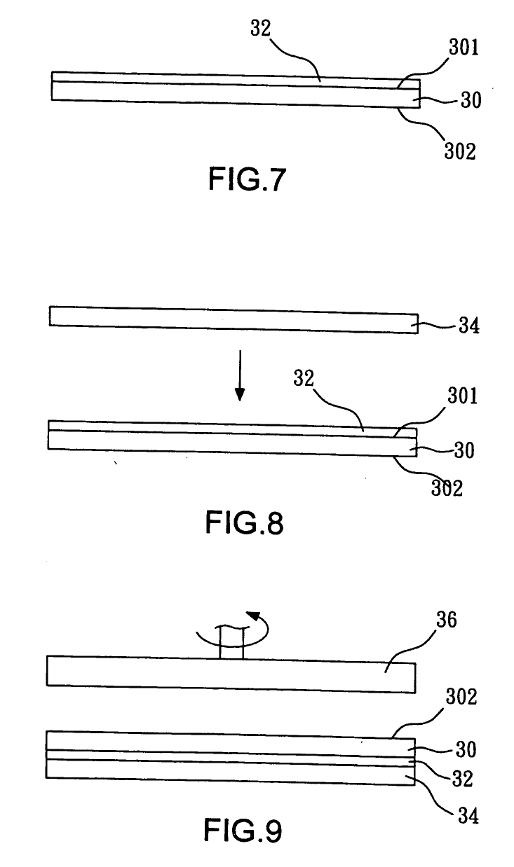

Referring to FIGS. 7 to 13, schematic views illustrating a method for machining a wafer according to the present invention are shown. Firstly, referring to FIG. 7, a wafer 30 having an active surface 301 and a backside surface 302 is provided, wherein the active surface 301 has a plurality of solder pads or sawing lines (not shown), etc. Then, an adhesive layer 32 is formed on the active surface 301 of the wafer 30. The adhesive layer 32 can be formed through printing or spin-coating.

Then, referring to FIG. 8, a plate substrate 34 is attached to the active surface 301 of the wafer 30, so as to protect the active surface 101 during the subsequent grinding process. The substrate 34 is a rigid substrate (e.g., a glass plate) and closely adhered to the wafer 30 by the adhesive layer 32, in order to support the wafer 30 during the subsequent moving and grinding processes, such that warping can be avoided as the thickness of the wafer 30 is reduced.

In this embodiment, the substrate 34 is adhered to the wafer 30 by the adhesive layer 32. However, it can be understood that the substrate 34 can also be attached to the active surface 301 of the wafer 30 through other ways.

Then, referring to FIG. 9, the wafer 30 is turned over 180 degrees, so that its backside surface 302 faces upwards to be machined. In this embodiment, the wafer 30 is placed onto a grinding machine, and the backside surface 302 of the wafer 30 is ground by a grinding wheel 36 of the grinding machine.

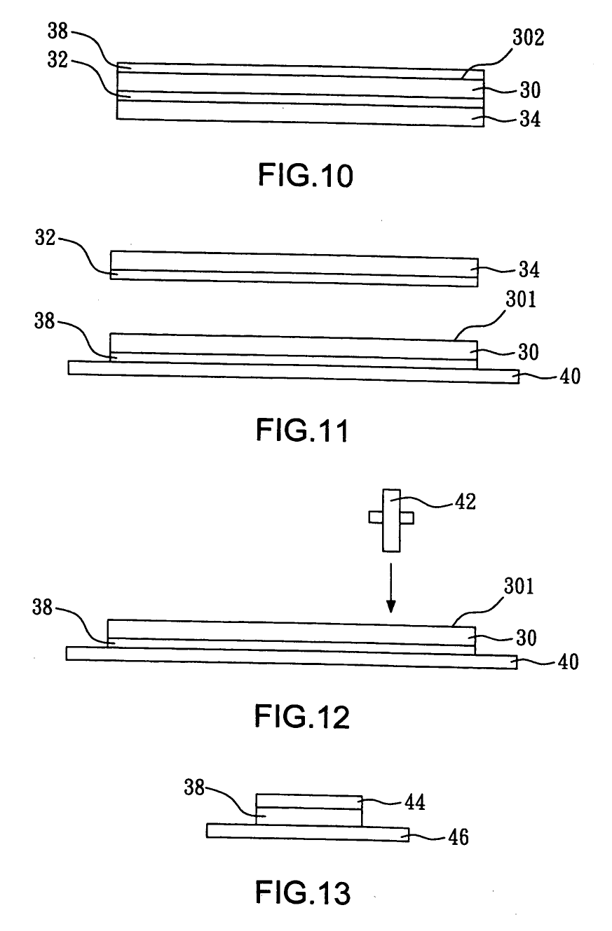

Then, referring to FIG. 10, an adhesive paste 38 is formed on the ground backside surface 302 of the wafer 30. The adhesive paste 38 is preferably a B-stage epoxy that formed on the backside surface 302 of the wafer 30 through printing or spin-coating. At this time, the B-stage epoxy is in an A-stage condition. Then, a curing process is carried out to make the B-stage epoxy become a B-stage condition.

Then, referring to FIG. 11, the wafer 30 is again turned over 180 degrees, so that its active surface 301 faces upwards. The wafer 30 is adhered onto a frame 40 by the adhesive paste 38. After that, the substrate 34 and the adhesive layer 32 are removed to expose the active surface 301 of the wafer 30.

Then, referring to FIG. 12, the wafer 30 is sawed along the sawing lines on the active surface 301 of the wafer 30 by a blade 42, to form a plurality of dies 44 (FIG. 13). After that, the dies 44 are picked out and then directly adhered onto a substrate 46 together with the adhesive paste 38. It should be noted that the process of adhering the dies 44 onto the substrate 46 requires heating and pressurization to make the B-stage epoxy become a C-stage condition, thus enhancing the adhering effects.

According to the present invention, since the dies 44 are adhered to the substrate 46 by the adhesive paste 38, the conventional liquid adhesive 24 is not needed, thus saving costs. In addition, as the B-stage epoxy is a half-curing adhesive, the glue overflow will not occur after the bonding process, and it can improve the yield of the product when used in the package structure of the stacked chips.

While several embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications which maintain the spirit and scope of the present invention are within the scope as defined in the appended claims.

What is claimed is:

1. A method for machining a wafer, comprising the following steps:
(a) providing a wafer having an active surface and a backside surface;
(b) attaching a plate substrate to the active surface of the wafer;
(c) grinding the backside surface of the wafer;
(d) removing the plate substrate; and
(e) sawing the wafer.

2. The method according to claim 1, wherein the step (b) is to form an adhesive layer on the active surface of the wafer, and then adhere the plate substrate to the active surface of the wafer.

3. The method according to claim 1, further comprising a step of turning over the wafer after the step (b).

4. The method according to claim 1, further comprising a step (c1) of forming an adhesive paste on the backside surface of the wafer after the step (c).

5. The method according to claim 4, wherein the adhesive paste is a B-stage epoxy.

6. The method according to claim 4, wherein the adhesive paste is formed on the backside surface of the wafer through spin-coating method.

7. The method according to claim 4, wherein the adhesive paste is formed on the backside surface of the wafer through printing method.

8. The method according to claim 4, further comprising a step (c2) of placing the wafer on a frame after the step (c1).

9. The method according to claim 1, wherein the plate substrate is a glass plate.
